(19) United States
(12) Patent Application Publication
(10) Pub. No.: US 2005/0046036 A1
(43) Pub. Date: Mar. 3, 2005

(54) Semiconductor device, semiconductor module and method of manufacturing semiconductor device

(75) Inventor: Toshihiro Iwasaki, Hyogo (JP)

Correspondence Address: McDermott, Will & Emery LLP, 600 13th Street, N.W., Washington, DC, 20005-3096, US

(73) Assignee: RENESAS TECHNOLOGY CORP

(21) Appl. No.: 10/924,967

(22) Filed: Aug. 25, 2004

(30) Foreign Application Priority Data
Sep. 1, 2003 (JP) 2003-309009(P)

(51) Int. Cl. H01L 23/48; H01L 23/52; H01L 29/40

(52) U.S. Cl. 257/777; 257/778; 257/738; 257/693

(57) ABSTRACT

A semiconductor device containing a semiconductor chip is provided with a coupling portion allowing coupling to a neighboring semiconductor device. The coupling portions couple the plurality of semiconductor devices to form a substrate, and a semiconductor package is arranged on the substrate via an electrode arranged on a surface of the substrate. This structure can improve a packaging density.

### BACKGROUND OF THE INVENTION

1. Field of the Invention

The present invention relates to a semiconductor device, a semiconductor module and a method of manufacturing a semiconductor device.

2. Description of the Background Art

(PriorArt 1)

Semiconductor devices, in which electronic parts including a plurality of semiconductor chips are mounted on a surface of a circuit board, have been available. In general, a circuit board is prepared by arranging interconnections and others on a base member, which is made of epoxy resin and has a predetermined configuration. Electronic parts such as a plurality of semiconductor packages and individual parts are arranged on one or both side(s) of the circuit board, and are connected to electrodes on the circuit board.

Japanese Patent Laying-Open No. 10-335570 has disclosed a semiconductor device including a combination of a plurality of semiconductor packages internally provided with semiconductor chips. In this semiconductor device, each semiconductor package is provided at its surface with a plurality of terminals, which are connected to the terminals on the neighboring semiconductor package.

In the above structure of arrangement in the semiconductor device, since the packages and others are arranged on a relatively thick substrate, a space corresponding to the thickness of the substrate is required, which causes a bottleneck in improvement of a packaging density. Further, in the structure of arranging a plurality of electronic parts, a dead space is formed between the packages. This likewise causes a bottleneck in improvement of the packaging density.

(Prior Art 2)

Japanese Patent Laying-Open No. 08-008392 has disclosed a semiconductor device, which includes a plurality of chips coupled together in a planar direction. In this semiconductor device, terminals arranged on side surfaces of the chips are joined together for electric connection. The above reference has also disclosed a structure, in which electrically conductive resin such as silver paste is arranged between the terminals for electric connection. Each chip is fixed onto a base material. The above reference has further disclosed a structure, in which the base material is made of a polyimide film or a polyester film, and interconnections made of copper foil are arranged on the base material for connection between only some chips.

Japanese Patent Laying-Open No. 11-330350 has disclosed a composite chip including a plurality of semiconductor chips fixed together by an elastic adhesive.

In the semiconductor device disclosed in the foregoing Japanese Patent Laying-Open No. 08-008392, the terminals arranged on the side surfaces of the semiconductor chips are joined together for electric connection. In the structure, which has the terminals joined together of connection, a contact failure may occur between the terminals if a space is formed between joined surfaces of the chips due to an external force. Therefore, this structure cannot be used if a force may be exerted to the joined surfaces of the chips. In the structure, which has the base material formed of a flexible film, and uses interconnections formed on the film for connection between some chips, flexibility can be ensured between the chips thus connected, but cannot be ensured between other chips.

(Prior Art 3)

Japanese Patent Laying-Open No. 2002-118198 has disclosed a semiconductor device, in which a semiconductor chip is arranged on an interconnection layer. Through holes are formed around the semiconductor chip, and are filled with an electrically conductive material, which serves as interconnections.

The above Japanese Patent Laying-Open No. 2002-118198 has disclosed the semiconductor device, in which the semiconductor chip is used alone, and has not disclosed a structure, in which semiconductor chips or the like are arranged in a stacked fashion.

(Prior Art 4)

Such a semiconductor device has been employed that a semiconductor chip is stacked on an insulated circuit board, and these are covered to provide a sealed integral structure.

In the semiconductor device having the semiconductor chip, which is stacked on the insulated circuit board and is sealingly covered together with the circuit board, a seal material and the insulated circuit board are made of materials impervious to light.

(Prior Art 5)

Usually, a semiconductor chip and a substrate holding the semiconductor chip are directly connected together by wire bonding or the like. This structure is disclosed in Japanese Patent Laying-Open No. 08-070077.

In the semiconductor device disclosed in the above Japanese Patent Laying-Open No. 08-070077, the substrate and the semiconductor chip are directly connected together by the wire bonding. The wire bonding usually uses thin metal wires. Since the substrate and the semiconductor chip are directly connected, the thin metal wires have a large total length. Due to this and others, a problem may occur, for example, if a high-frequency current flows through the wires.

(Prior Art 6)

Japanese Patent Laying-Open No. 2001-135781 has disclosed a semiconductor device having two semiconductor chips vertically stacked together. The lower semiconductor chip is connected to a substrate by a bump formed on a lower surface of the semiconductor chip. The upper semiconductor chip is provided at its upper surface with electrodes, which are connected to electrodes on the substrate by wire bonding.

A semiconductor device disclosed in Japanese Patent Laying-Open No. 2000-124395 includes two semiconductor chips, which are vertically stacked together. The lower semiconductor chip is located lower than a lead frame, and is provided at its lower surface with a bump for external connection. The upper chip is provided at its upper surface with electrodes connected to a lead frame by wire bonding.

According to the semiconductor device disclosed in the foregoing Japanese Patent Laying-Open No. 2001-135781, the lower semiconductor chip is always connected externally via the substrate. This restricts the flexibility in interconnection design.

According to the semiconductor device disclosed in the foregoing Japanese Patent Laying-Open No. 2000-124395, the lower semiconductor chip can be directly connected to an external portion. However, the electrode formed on the lower surface of the lower semiconductor chip cannot be connected directly to the lead frame.

### SUMMARY OF THE INVENTION

(First Invention)

The first invention has been developed for overcoming the problem already described in connection with the prior art 1, and it is an object of the invention to provide a semiconductor device, a semiconductor module and a method of manufacturing a semiconductor device.

According to an aspect of the invention, a semiconductor device includes a circuit board having first and second main surfaces, and provided at the fist main surface with an electrode; a semiconductor chip connected to the second main surface of the circuit board; a sealing member sealingly covering the circuit board and the semiconductor chip while exposing the first main surface of the circuit board; and a coupling portion allowing coupling to a neighboring semiconductor device.

According to an aspect of this invention, a method of manufacturing a semiconductor device includes the steps of: arranging a plurality of semiconductor devices each including having first and second main surfaces, a semiconductor chip connected to the first main surface of the circuit board and a sealing member sealingly covering the circuit board and the semiconductor chip while exposing the second main surface of the circuit board on an adhesive surface of an adhesive tape in an expanded state; and shrinking the adhesive tape to couple the plurality of semiconductor devices together by bringing the semiconductor devices into intimate contact with each other.

(Second Invention)

A second invention has been developed for overcoming the problem already described in connection with the prior art 2, and it is an object of the invention to provide a semiconductor device, which can ensure sufficient flexibility by combining semiconductor chips, and can avoid a disadvantage due to deformation even when the deformation occurs to a certain extent, as well as a method of manufacturing the semiconductor device.

According to an aspect of this invention, a semiconductor device includes a plurality of semiconductor chips coupled together via a stress absorbing layer, and one or some of the plurality of semiconductor chips have main surface(s) inclined with respect to the main surface(s) of the other semiconductor chip(s).

(Third Invention)

A third invention has been developed for overcoming the problem already described in connection with the prior art 3, and it is an object of the invention to provide a semiconductor device, which allows wiring or interconnection arrangement suitable to a structure having semiconductor chips or the like in a stacked fashion.

According to an aspect of this invention, a semiconductor device includes a substrate; a base member fixed onto the substrate with its first main surface opposed to the substrate; and a semiconductor chip fixed to a second main surface of the base member. The base member is provided at a portion not overlapping with the semiconductor chip with an electrically conductive member extending from the first main surface of the base member to the second main surface of the base member. The side of the electrically conductive member near the first main surface is connected to an electrode arranged on the substrate, and a side of the electrically conductive member near the second main surface is electrically connected directly or via an interconnection to an electrode of the semiconductor chip.

(Fourth Embodiment)

A fourth invention has been developed for overcoming the problem already described in connection with the prior art 4, and it is an object of the invention to provide a semiconductor device, in which a semiconductor chip is laid on an insulated circuit board, and is sealingly covered together with the insulated circuit board, and particularly to provide the semiconductor device, which allows external light to reach the semiconductor chip.

According to an aspect of this invention, a semiconductor device includes a base member; and a semiconductor chip fixed to a first main surface of the base member. The base member is formed of a base member body, and a light transmitting member extending through the base member body. A sealing member sealingly covers the semiconductor chip and the base member while externally exposing at least a portion of the light transmitting member, and the light transmitting member leads external light to the semiconductor chip.

(Fifth Invention)

A fifth invention has been developed for overcoming the problem already described in connection with the prior art 5, and it is an object of the invention to provide a semiconductor device having an interconnection structure, which can lead a high-frequency current to a semiconductor chip without a problem.

According to an aspect of this invention, a semiconductor device includes a circuit board; a semiconductor chip arranged on the circuit board; and a flexible substrate having a first end coupled to the circuit board and a second end coupled to the semiconductor chip. A pad formed on the semiconductor chip is electrically connected to a terminal formed on the flexible substrate.

(Sixth Invention)

A sixth invention has been developed for overcoming the problem already described in connection with the prior art 6, and it is an object of the invention to provide a semiconductor device and a method of manufacturing the semiconductor device. The semiconductor device has two semiconductor chips at lower and higher positions. A connection between each of electrodes arranged on a lower surface of the lower chip and a lead frame or an external portion can be made by freely selecting and directly connecting the lead frame or the external portion to the electrode depending on necessity in design.

According to an aspect of this invention, a semiconductor device includes a lead frame; a first semiconductor chip fixed to a main surface of the lead frame, and having a first main surface opposed to the main surface of the lead frame; and a second semiconductor chip fixed to a second main surface of the first semiconductor chip. The lead frame has an opening in a position corresponding to at least one of electrodes formed on the first main surface of the first semiconductor chip.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an elevation showing a semiconductor module in a first embodiment according to a first invention.

FIG. 2 is a cross section showing the semiconductor module in the first embodiment according to the first invention.

FIG. 3 is a plan showing a coupling structure of a plurality of semiconductor devices in the first embodiment according to the invention.

FIG. 4 is a plan showing a structure of electrically and mutually connecting semiconductor devices in the first embodiment according to the first invention.

FIGS. 5-7 are elevations showing modifications of the first embodiment according to the first invention.

FIG. 8 is an elevation showing a connection structure using a flexible substrate in a modification of the first embodiment according to the first invention.

FIG. 9 is a cross section showing a semiconductor module of a modification of the first embodiment according to the first invention.

FIG. 10 is a cross section showing a semiconductor device of a second embodiment according to a second invention.

FIG. 11 is a plan showing a semiconductor device of a second embodiment according to the second invention.

FIG. 12 is a plan showing an electric connection structure between semiconductor chips forming the semiconductor device of the second embodiment according to the second invention.

FIG. 13 is an elevation showing a structure of fixing the semiconductor chips together by an adhesive tape in the semiconductor device of the second embodiment according to the second invention.

FIG. 14 is a cross section showing a structure of connecting the semiconductor chips by a flexible substrate in the semiconductor device of the second embodiment according to the second invention.

FIG. 15 is a cross section showing a structure of a modification of the semiconductor device of the second embodiment according to the second invention.

FIG. 16 is a cross section of a semiconductor device of a third embodiment according to a third invention.

FIG. 17 is a cross section of a semiconductor device of a fourth embodiment according to a fourth invention.

FIG. 18 is a cross section of a semiconductor device of a fifth embodiment according to a fifth invention.

FIG. 19 is a cross section showing a modification of the semiconductor device of the fifth embodiment according to the fifth invention.

FIG. 20 is a cross section of a semiconductor device of a sixth embodiment according to a sixth invention.

FIG. 21 is a plan showing a lead frame in the semiconductor device of the sixth embodiment according to the sixth invention.

FIG. 22 is a cross section of a modification of the semiconductor device of the sixth embodiment according to the sixth invention.

### DESCRIPTION OF THE PREFERRED EMBODIMENTS

(First Embodiment)

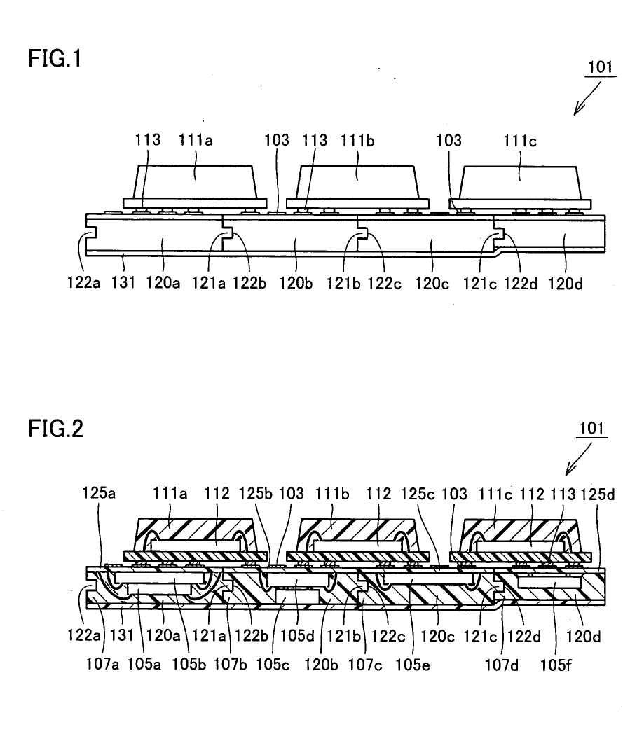

A semiconductor device, a semiconductor module and a method of manufacturing the semiconductor device of a first embodiment according to a first invention will now be described with reference to FIGS. 1 to 11.

As shown in FIG. 1, a semiconductor module 101 of the first embodiment is formed of a plurality of semiconductor devices 120a-120d forming a substrate, and a plurality of electronic parts 111a-111c arranged on the substrate formed of semiconductor devices 120a-120d coupled together.

According to the first embodiment, each electronic part 111 is formed of a semiconductor package containing a semiconductor chip 112. Instead of the semiconductor package thus formed, electronic part 111, which is arranged on the substrate formed of semiconductor devices 120a-120d coupled together, may be formed of an individual part such as a resistance or a capacitor.

Each semiconductor package forming electronic part 111 of this embodiment is a BGA (Ball Grid Array) package, and is provided at its lower surface with solder bumps 113 for electric connection to electrodes 103. Instead of the BGA package, the semiconductor package may be of a pin lead type, in which pins are inserted for connection, or a gull-wing lead type. For employing these types of semiconductor packages, holes for inserting pins or lands for mounting are formed on the surfaces of semiconductor devices 120a-120d so that the semiconductor packages can be mounted.

As shown in FIG. 2, each of semiconductor devices 120a-120d is internally provided with one or a plurality of semiconductor chips 105a-105f. These semiconductor chips 105 are fixed onto insulated circuit boards 125a-125d. Each insulated circuit board 125 and corresponding semiconductor chip 105 are connected together by flip-chip connection utilizing solder bumps or by wire bonding. These insulated circuit boards 125 provide interconnections for mutually connecting electronic parts 111, which are arranged on the substrate formed of semiconductor devices 120a-120d.

Semiconductor devices 120a-120d forming the substrate are provided with sealing members 107a-107d, respectively, which sealingly cover semiconductor chips 105a-105f Sealing member 107 is arranged to expose a main surface of insulated circuit board 125 carrying electrodes 103.

Electrodes 103 are formed on the surface of each semiconductor device 120. A connection material such as a solder material, electrically conductive resin or an anisotropic conductive resin may be arranged in advance on electrodes 103.

In a conventional structure, an independent substrate made of epoxy resin or the like is arranged, and electronic parts are arranged on the opposite surfaces of the substrate. In this structure, the independent substrate must ensure an appropriate rigidity by itself, and therefore has a relative large thickness. In contrast to this conventional structure, the plurality of electronic parts 111 are directly arranged on the substrate, which is formed of the plurality of semiconductor devices 120a-120d coupled together, according to this embodiment so that an independent thick substrate is not required in contrast to the conventional structure, and the thickness can be reduced. Therefore, a packaging density can be improved.

As shown in FIG. 1, the substrate in the embodiment is formed of the combination of the plurality of semiconductor devices 120a-120d. As coupling portions, semiconductor devices 120 have convexities or ridges 121a-121c for engagement with neighboring semiconductor devices 120 as well as grooves 122a-122d, into which ridges 121a-121c of the neighboring packages are fitted, respectively. As described above, this embodiment includes, as the coupling portions for mechanically connecting semiconductor devices 120 together, the foregoing fitting portions formed of ridges 121a-121c and grooves 122a-122d fitted together. The fitting portions serving as the coupling portions may be formed of structures others than the ridges and grooves. For example, the fitting portions may be formed of a plurality of projections projected from an end surface of semiconductor device 120 and holes formed at the end surface of neighboring semiconductor device 120 for engagement with the projections. The coupling portions formed of the fitting portions thus configured can reliably couple semiconductor devices 120 together, and can easily position semiconductor devices 120 in a coupling operation.

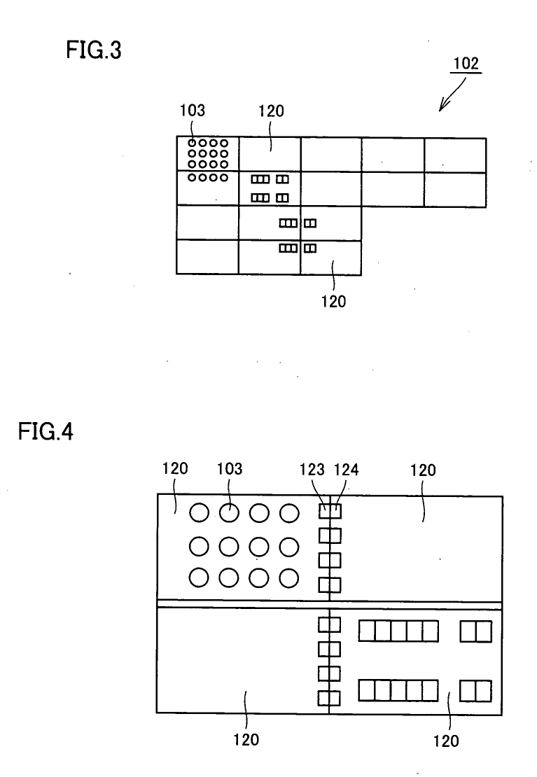

By arranging semiconductor devices 120 as shown in FIG. 3, it is possible to form the substrate having a planar form, e.g., shown in FIG. 3. Since each semiconductor device 120 has a rectangular main surface, semiconductor devices 120 can be easily connected in the planar direction. Instead of the rectangular form, each semiconductor device 120 may have a triangular, hexagon or octagonal form.

For mutually fixing semiconductor devices 120 together, an adhesive tape 131 shown in FIG. 1 may be employed. It is preferable that adhesive tape 131 is expandable. By using expandable adhesive tape 131, semiconductor devices 120a-120d can be coupled through the following steps.

Adhesive tape 131 is expanded with its adhesive surface upward. Semiconductor devices 120a-120d are arranged on the adhesive surface of adhesive tape 131, and are adhered thereto. Then, a force expanding adhesive tape 131 is released therefore to shrink adhesive tape 131 so that semiconductor devices 120a-120d are brought into intimate contact with each other. In this manner, the plurality of semiconductor devices 120a-120d can be easily integrated to form the substrate. In the above structure, adhesive tape 131 also forms the coupling portion mechanically coupling semiconductor devices 120a-120d together.

Instead of the adhesive tape, the coupling portion may employ solder or adhesive. Also, coupling by the solder or adhesive may be employed together with the coupling by adhesive tape 131. The coupling portion may employ the coupling by adhesive tape 131, solder and/or adhesive together with the foregoing fitting portion.

Expandable adhesive tape 131 may be formed of film, e.g., of vinyl chloride, polyolefine or polyethylene terephthalate (PET) coated with a sticky adhesive layer. Adhesive tape 131 may be formed of a heat-shrinkable film coated with an adhesive layer.

For electric connection between semiconductor devices 120, as shown in FIG. 4, semiconductor device 120 is provided at a base portion of ridge 121 with connection terminals 123 serving as connection portions. Likewise, semiconductor device 120 is provided at an upper edge of groove 122 with connection terminals 124, which are located in positions corresponding to connection terminals 123 on ridge 121, and serve as the connection portions, respectively. By combining the semiconductor devices 120, connection terminals 123 and 124 come into contact with each other, and thereby electrically connect semiconductor devices 120 together. For ensuring conduction between connection terminals 123 and 124 more reliably, an electrically conductive material such as an anisotropic conductive material may be arranged between them. Electrodes metallized by plating or the like may be formed on the side surface of semiconductor device 120 for forming the connecting portion, and the electric connection may be performed by metal connection using nonconductive resin.

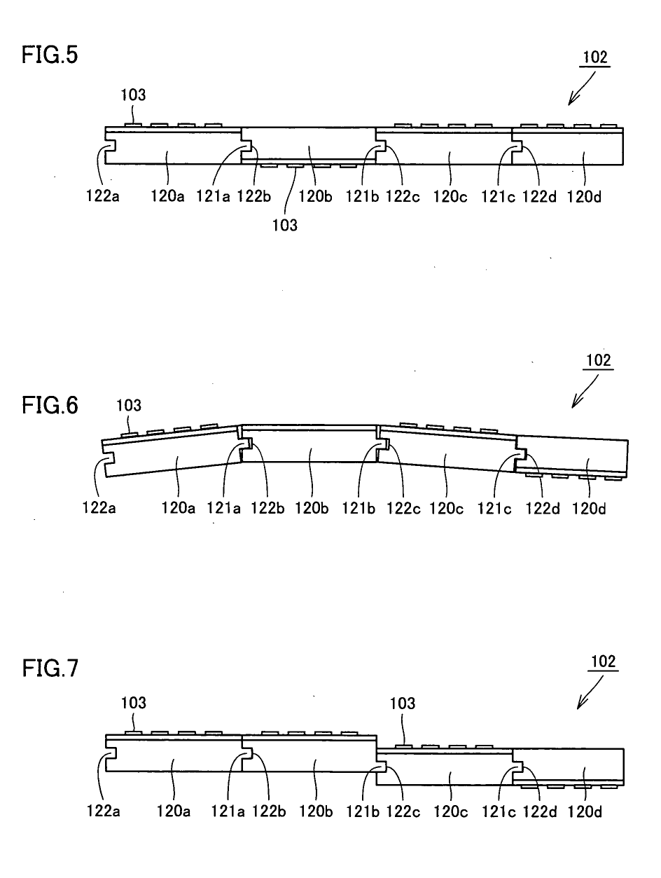

For example, as shown in FIG. 5, only semiconductor device 120b may be arranged upside down. In this structure, only electrodes 103 formed on semiconductor device 120b are located on the lower side so that the substrate provided at its opposite surfaces with electrodes 103 can be easily formed. In this embodiment, the coupling portion is formed of ridges 121 and grooves 122, and each of ridges 121 and grooves 122 is substantially located at a center in the direction of the thickness of semiconductor device 120. Thereby, the main surface of semiconductor device 120 provided with electrodes 103 may be selectively located on the upper side and the lower side in the structure formed of semiconductor devices 120 connected together.

In a modification shown in FIG. 6, semiconductor devices 120a-120d are coupled to provide the substrate having a curved main surface. In this substrate, each semiconductor device 120 has a flat surface, but spaces are formed between semiconductor devices 120a-120d so that the main surface of the substrate may be curved as a whole. In the case where a semiconductor module is to be packaged within a casing having a curved main surface, the above curved structure allows such packaging, and improves the packaging density. In the structure having semiconductor devices 120, which are coupled together in the inclined positions, ridges 121a-121c may be formed in positions inclined with respect to the main surfaces of semiconductor devices 120. Grooves 122a-122d may be formed in positions inclined with respect to the main surfaces of semiconductor devices 120. Ridges 121a-121c and grooves 122a-122d may be inclined with respect to the main surfaces of semiconductor devices 120. This structure facilitates an operation of coupling semiconductor devices 120 inclined with respect to each other at a constant inclination angle.

In a modification shown in FIG. 7, a stepped portion causing a difference in level is formed at the main surface of the substrate formed of semiconductor devices 120a-120d coupled together. Ridge 121b of semiconductor device 120b neighboring to the stepped portion is formed along the lower surface of semiconductor device 120b. Groove 122c of semiconductor device 120c neighboring the stepped portion is formed substantially at a center in the direction of thickness of semiconductor device 120c. By fitting ridge 121b thus formed into groove 122c, the difference in level is formed between the main surfaces of semiconductor devices 120b and 120c. According to this structure, the semiconductor module including semiconductor devices 120a-120d can be arranged in a space, which requires a stepped portion on the main surface of the substrate for arrangement, so that the packaging density can be improved.

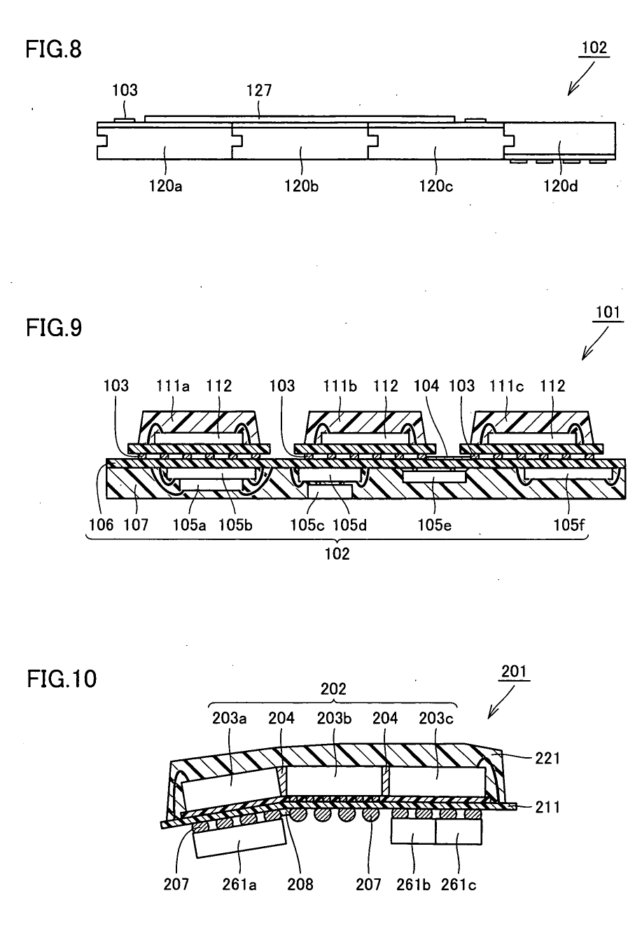

In FIG. 8, a flexible substrate 127 is used for electrically connecting semiconductor devices 120a-120c together. Flexible substrate 127 is formed of a base member made of, e.g., polyimide film and interconnections, which are made of copper foil and are arranged on the base member. By mutually connecting semiconductor devices 120 with flexible substrate 127, wiring or interconnection arrangement can be designed more flexibly.

According to the embodiment described above, the plurality of semiconductor devices 120, each of which has a rectangular form when viewed perpendicularly to the first main surface, are coupled in the direction of the first main surface so that the substrate expanded in the planar direction can be formed by the combination of relatively small semiconductor devices 120. This structure can use semiconductor devices 120, each of which is individually tested, and therefore can achieve a higher yield than a structure having a substrate formed of single semiconductor device 120. By changing a combination of semiconductor devices 120, the substrates having various forms can be selectively formed.

Referring to FIG. 9, a modification of this embodiment will now be described.

In the foregoing embodiment, the plurality of semiconductor devices 120 are combined to form the substrate. In the following modification, the substrate is formed of a semiconductor device 102, which is expanded in the planar direction, as compared with the conventional semiconductor device. Semiconductor device 102 is provided at its surface with a plurality of electrodes 103 and interconnections 104. These electrodes 103 and interconnections 104 are arranged for connection to electronic parts 111 arranged on the surface of semiconductor device 102 as well as mutual connection between electronic parts 111a-111d. It is not essential to arrange interconnections 104 on the surface of the substrate, and interconnections 104 may be arranged within semiconductor device 102.

Semiconductor device 102 having large sizes in this embodiment can be produced by transfer mold having an increased region, in which resin coating is performed at a time.

A plurality of semiconductor chips 105 are arranged inside semiconductor device 102, and are collectively covered in a sealed fashion. This structure can reduce a distance between semiconductor chips 105, as compared with a structure having a plurality of packages individually containing the semiconductor chips. This reduces a packaging area of semiconductor chips 105a-105f, and improves the packaging density.

In summary, according to the structure of the above modification, semiconductor device 102 containing semiconductor chips 105 is employed, and electrodes 103 and interconnections 104 connected to electrodes 103 are arranged on the first main surface of semiconductor device 102 to form the substrate. The plurality of electronic parts 111 electrically connected to electrodes 103 are arranged on the first main surface of semiconductor device 102 to form semiconductor module 101 of this modification. This structure of semiconductor module 101 can increase the packaging density.

(Second Embodiment)

A semiconductor device and a method of manufacturing the same in a second embodiment according to a second invention will now be described with reference to FIGS. 10 to 15.

As shown in FIG. 10, a semiconductor device 202 of this embodiment has a plurality of semiconductor chips 203a-203c. Semiconductor chip 203a has a main surface inclined with respect to main surfaces of semiconductor chips 203b and 203c. Semiconductor device 202 is electrically connected to insulated circuit board 211 serving as a base member. This semiconductor device 202 is sealingly covered with a sealing member 221 to form a semiconductor package 201.

A plurality of electrodes 207 are arranged on the lower surface of insulated circuit board 211. Interconnections 208 are arranged in appropriate positions between electrodes 207. Semiconductor package 201 also includes a plurality of electronic parts 261 connected to electrodes 207.

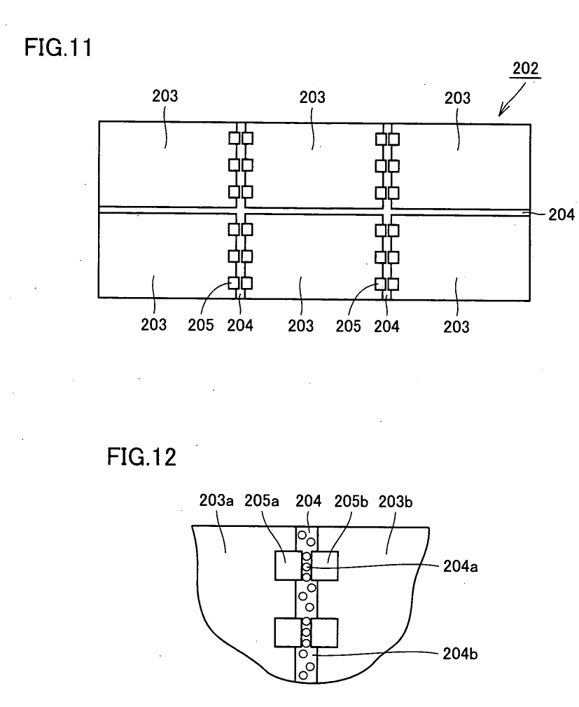

As shown in FIGS. 10 and 11, semiconductor device 202 is formed of a plurality of semiconductor chips 203 coupled together. Neighboring semiconductor chips 203 are coupled together by a stress absorbing layer 204. According to this structure, even when a semiconductor chip assembly 202 deforms due to a force exerted thereto, the stress absorbing layer can absorb such deformation, and can prevent breakage of semiconductor chips 203.

As described above, stress absorbing layers 204 are arranged between semiconductor chips 203. Stress absorbing layer 204 may be formed of an anisotropic conductive material having conductivity, or may be formed of liquid resin not having conductivity. For electrically connecting semiconductor chips 203 together, stress absorbing layer 204 made of the anisotropic conductive material is arranged throughout the space between semiconductor chips 203. If electric connection between semiconductor chips 203 is not necessary, stress absorbing layer 204 made of the liquid resin not having conductivity is arranged throughout the space between semiconductor chips 203.

Semiconductor chips 203 to be electrically connected together are provided at portions of their edges with connection terminals 205a and 205b opposed to each other. The anisotropic conductive material is arranged between connection terminals 205a and 205b opposed to each other. The anisotropic conductive material is made of resin 204b not having conductivity and conductive particles 204a, which are spaced from each other and are dispersed in resin 204b. As shown in FIG. 12, neighboring connection terminals 205a and 205b hold conductive particles 204a therebetween, and thereby are electrically connected to each other. Meanwhile, an insulated state is kept between the connection terminals, which are not close to each other. Resin 204b is flexible to a certain extent. Thereby, semiconductor chips 203 can be electrically connected together while keeping flexibility between semiconductor chips 203 and keeping an insulated state between neighboring connection terminals 205. Even when the main surface of semiconductor chip 203 is inclined, the anisotropic conductive material described above allows easy connection of connection terminal 205.

Semiconductor chip assembly 202 is fixed onto insulated circuit board 211 as shown in FIG. 10. Semiconductor chips 203a and 203c are fixed to insulated circuit board 211 by diebond resin or the like. Semiconductor chips 203a and 203c are electrically connected to insulated circuit board 211 by wire bonding. According to this structure, even when insulated circuit board 211 is deformed by a force to a certain extent, the diebond resin and stress absorbing layer 204 can absorb the deformation so that the force applied to semiconductor chips 203a, 203b and 203c can be smaller than that applied to a semiconductor chip of an integrated form having substantially the same sizes as semiconductor chip assembly 202. A lead frame may be used instead of insulated circuit board 211.

Semiconductor chip 203b and insulated circuit board 211 are connected by flip-chip connection. Thereby, the mechanical connection and electric connection of semiconductor chip 203b to insulated circuit board 211 can be performed at the same time.

Semiconductor device 202 including the plurality of semiconductor chips 203 is integrated by sealing member 221. Since sealing member 221 is an organic material, it has certain flexibility. Even when sealing member 221 is deformed by a force, stress absorbing layer 204 can absorb the deformation because semiconductor device 202 is formed of semiconductor chips 203 coupled via stress absorbing layer 204. Thereby, it is possible to avoid breakage of semiconductor chip 203a. Since semiconductor chip 203a forming semiconductor device 202 has the main surface inclined with respect to the main surfaces of semiconductor chips 203b and 203c, semiconductor package 201 covering them can have a partially inclined form as shown in FIG. 10. Owing to this structure, semiconductor package 201 can be arranged in a partially bent space.

Since stress absorbing layer 204 is arranged between semiconductor chips 203, the main surfaces of all semiconductor chips 203 may be positioned on the same plane when mutually coupling semiconductor chips 203, and in a later step, the main surfaces of one or some semiconductor chip(s) 203 may be inclined with respect to the main surface(s) of the other semiconductor chip(s) 203 to provide semiconductor device 202. This step of inclining one or some of semiconductor chip(s) 203 with respect to the other semiconductor chip(s) 203 may be performed, e.g., as follows. Semiconductor chips 203 are coupled together via stress absorbing layers 204 to provide semiconductor device 202 of a flat form. Flat semiconductor device 202 thus formed is fixed to insulated circuit board 211, which is already bent. Thereby, flat semiconductor device 202 is partially bent along insulated circuit board 211 to provide semiconductor device 202, in which the main surface(s) of one or some semiconductor chip(s) 203 are inclined with respect to the main surface(s) of the other semiconductor chip(s) 203.

This embodiment provides the semiconductor chip of a large size by combining the plurality of semiconductor chips, each of which exhibits a good yield, is inexpensive and has a relatively small size. Thereby, the semiconductor chip of a large size can be manufactured with a good yield and at a low cost. The semiconductor chips can be handled by an ordinary package assembling process, and therefore can be easily handled. Although a large semiconductor package is liable to be warped or curved, the semiconductor package formed of the semiconductor chips of the invention can absorb such warping by stress absorbing layer 204, and thus can prevent a problem such as breakage of semiconductor chip 203.

In this embodiment, semiconductor chip 203 has a rectangular form in a plan view. This facilitates connection of the chips in the planar direction. However, semiconductor chip 203 may have another form such as a triangular, hexagon or octagonal form.

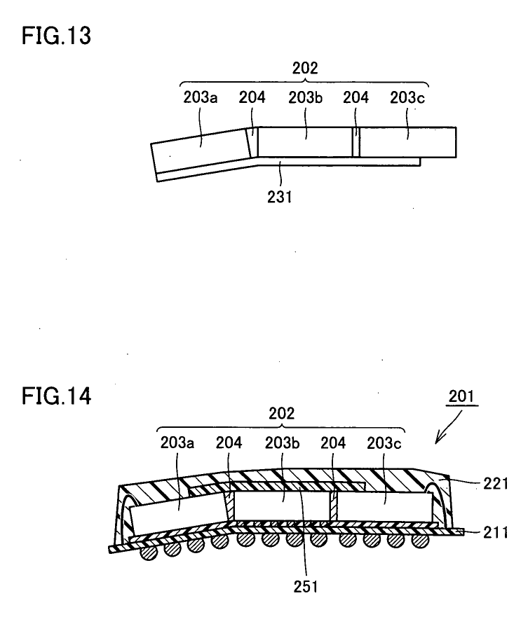

For mutually fixing semiconductor chips 203, an adhesive tape 231 shown in FIG. 13 may be used. Preferably, adhesive tape 231 is expandable. By using expandable adhesive tape 231, semiconductor chips 203 can be coupled through the following steps.

First, adhesive tape 231 is expanded with its adhesive surface upward. Semiconductor chips 203 are arranged on the adhesive surface of adhesive tape 231, and are adhered thereto. Then, spaces between semiconductor chips 203 are filled with resin, which will form stress absorbing layers 204. Then, a force expanding adhesive tape 231 is released to shrink adhesive tape 231 so that semiconductor chips 203 come into intimate contact with each other. Finally, one or some semiconductor chip(s) 203a is inclined, if necessary, and the resin forming stress absorbing layer 204 is cured. The manner described above can easily provide semiconductor chip assembly 202 having the plurality of semiconductor chips 203 in the integrated fashion. Expandable adhesive tape 231 may be formed of film, e.g., of vinyl chloride, polyolefine or polyethylene terephthalate (PET) coated with a sticky adhesive layer. Adhesive tape 231 may be formed of a heat-shrinkable film coated with an adhesive layer.

In semiconductor device 202 shown in FIG. 14, flexible substrates 251 are arranged between semiconductor chips 203 contained in semiconductor device 202. Each flexible substrate 251 electrically connects neighboring semiconductor chips 203 together. Flexible substrate 251 is formed of a base member such as polyimide film and interconnections, which are made of copper foil and are laid over the base member. Electrodes connected to flexible substrate 251 are arranged on the upper surfaces of semiconductor chips 203, and are electrically connected to interconnections arranged on flexible substrate 251.

Mutual electric connection between semiconductor chips 203 may be performed only by this flexible substrate, or may be performed by additionally utilizing connection using the foregoing conductive resin. Use of flexible substrate 251 can improve the flexibility in interconnection design of semiconductor device 202, and can improve the strength of semiconductor device 202.

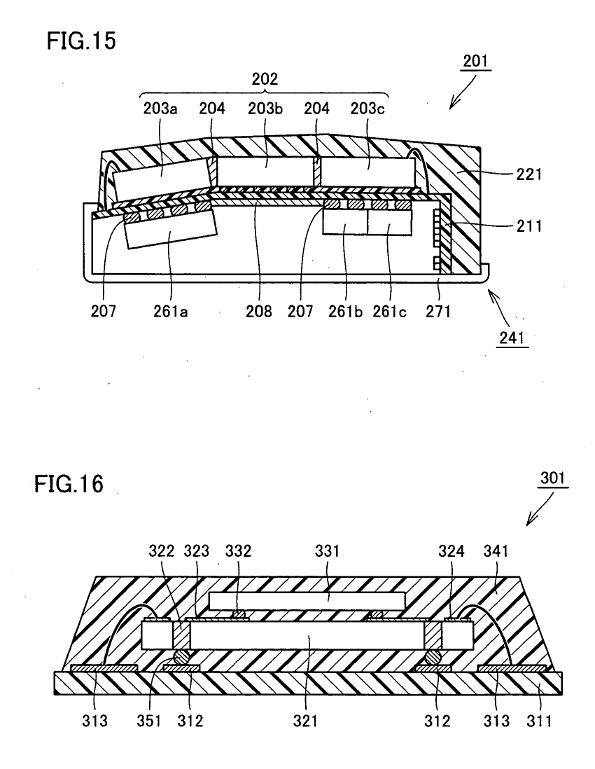

According to this embodiment, as shown in FIG. 15, semiconductor package 201, which includes sealing member 221 covering semiconductor device 202, forms a part of a casing 241 of electronic devices. Semiconductor package 201 has a function as the base member or substrate, and the plurality of electronic parts 261 are arranged on the inner surface of semiconductor package 201.

Semiconductor package 201 according to the embodiment has an L-shaped section, and a cover 271 is engaged with opposite edges of semiconductor package 201 for connection. Semiconductor package 201 and cover 271 form casing 241. Casing 241 may be a casing of a cellular phone or the like. The package of large sizes in this embodiment can be manufactured by transfer mold having an increased region, in which resin coating is performed at a time. The upper surface of casing 241 in FIG. 15 has an inclined portion. For matching with such inclination, semiconductor chip 203a has the main surface inclined with respect to the main surfaces of semiconductor chips 203b and 203c.

Electronic parts 261 are arranged in a space defined by semiconductor package 201 and cover 271, as already described. Electronic parts 261 may be semiconductor packages containing semiconductor chips, or may be independent parts such as resistances or capacitors.

On the inner surface of semiconductor package 201, there are arranged electrodes 207, which are electrically connected to electronic parts 261. All electronic parts 261 employ BGA (Ball Grid Array) packages, and are electrically connected to electrodes 207 via balls, which are arranged on the lower surface of the package.

Interconnections 208 are arranged between electrodes 207 for connection between electronic parts 261. Interconnections 208 may be arranged inside semiconductor device 202 connected to insulated circuit board 211 or on the surface of semiconductor device 202.

The structure described above can improve the packaging density, and can also achieve effects such as reduction of a weight owing to reduction in number of parts. Various kinds of external forces may act on the casing to deform the casing. However, stress absorbing layer 204 arranged between semiconductor chips 203 can absorb such deformation so that a problem due to deformation can be prevented. Even when deformation occurs due to thermal expansion of the sealing member forming a part of the casing, stress absorbing layer 204 can absorb such deformation.

According to this embodiment, the structure of the invention can be summarized as follows. In semiconductor device 202 of this embodiment, the plurality of semiconductor chips 203 are coupled together via stress absorbing layers 204 arranged between semiconductor chips 203, and one or some semiconductor chip(s) have the main surface(s) inclined with respect to the main surface(s) of the other semiconductor chip(s) 203. This structure allows arrangement of semiconductor package 201 in a space having a bent or curved portion, and thus improves the packaging density of the device incorporating semiconductor package 201. Since stress absorbing layers 204 are arranged between semiconductor chips 203, the main surfaces of all semiconductor chips 203 may be positioned on the same plane when mutually coupling semiconductor chips 203, and in a later step, if necessary, the main surfaces of one or some semiconductor chip(s) 203 may be inclined with respect to the main surface(s) of the other semiconductor chip(s) 203.

Semiconductor device 202 is covered by sealing member 221 in an integrated fashion, and preferably, sealing member 221 forms a part of casing 241 of the electronic part. Each semiconductor chip 203 is provided at its edge with connection terminals 205 for electric connection to neighboring semiconductor chip 203. Preferably, flexible substrate 251 electrically connects semiconductor chips 203 together.

Insulated circuit board 211 serving as a base member connected to semiconductor device 202 is further employed, and is connected to at least one semiconductor chip 203 forming semiconductor device 202 by flip-chip connection. At least one of the other semiconductor chips 203 forming semiconductor device 202 is connected to insulated circuit board 211 by wire bonding.

(Third Embodiment)

A semiconductor device of a third embodiment according to a third invention will now be described with reference to FIG. 16.

As shown in FIG. 16, a semiconductor device 301 of this embodiment includes a substrate 311, a base member 321 fixed onto substrate 311 and having a first main surface opposed to substrate 311, and a semiconductor chip 331 fixed to a second main surface of base member 321. Conductive members 322 extending between the first and second main surfaces of base member 321 are arranged in a portion of base member 321 not overlapping with semiconductor chip 331. An end of conductive member 322 near the first main surface is electrically connected to an electrode 332 of semiconductor chip 331 via interconnection 323. An end of conductive member 322 near the second main surface is connected to an electrode arranged on substrate 311.

Substrate 311 is formed of an insulated circuit board, and is provided on its surface with electrodes 312 and 313. Electrode 312 is electrically connected to the lower end of conductive member 322 via a solder bump 351. Electrode 313 is connected to an electrode 324 formed on the surface of base member 321 by wire bonding.

Semiconductor chip 331 is provided on its lower surface with electrodes 332. Solder bumps are arranged on electrodes 332, and electrodes 332 are connected to interconnections 323 of the base member by flip-chip connection. Base member 321 may be merely formed of a silicon substrate having neither a semiconductor chip nor another semiconductor element.

Through holes are formed in only an outer portion of base member 321 not overlapping with semiconductor chip 331, and are filled with conductive members 322. These through holes can be formed, e.g., by wet etching or laser radiation. Conductive members 322 can be formed, e.g., by metal plating.

Base member 321 and semiconductor chip 331 are covered by a sealing member 341.

In the semiconductor device of this embodiment, conductive members 322 are arranged in only the outer portion of base member 321 not overlapping with semiconductor chip 331. Therefore, the interconnections to the electrodes of semiconductor chip 331 can have simple structures, as compared with the case, in which conductive members 322 are additionally arranged in positions overlapping with semiconductor chip 331. Therefore, it is not necessary to form multi-layer interconnections on base member 321, and thus the structure can be inexpensive.

(Fourth Embodiment)

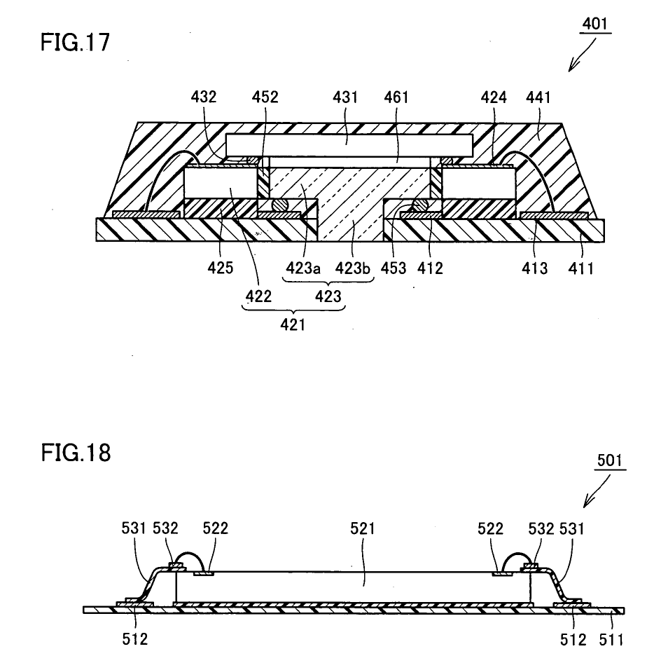

A semiconductor device of a fourth embodiment according to a fourth invention will now be described with reference to FIG. 17.

The semiconductor device of this embodiment has a base member 421 and a semiconductor chip 431 fixed to a first main surface of base member 421. Base member 421 is formed of a base member body 422 and a light transmitting member 423. A sealing member 441 sealingly covers semiconductor chip 431 and base member 421 while externally exposing at least a portion of light transmitting member 423. Base member 421 is fixed to a substrate 411.

Substrate 411 is formed of a base member made of, e.g., epoxy resin as well as electrodes 412 and 413 and interconnections (not shown) formed on the base member. Substrate 411 is provided at its central portion with a though hole fitted with a lower end of light transmitting member 423.

Base member 421 is formed of base member body 422 and light transmitting member 423 fixed to base member body 422 by an adhesive 452. Base member body 422 is formed of, e.g., a silicon substrate not having a semiconductor element, and is provided at its central portion with the though hole engaged with light transmitting member 423. Base member body 422 is provided at its upper surface with an electrode 424 having an end connected to semiconductor chip 431. The other end of electrode 424 is connected to electrode 413 on substrate 411 by wire bonding. Base member body 422 is fixed to substrate 411 by a diebond material 425.

Light transmitting member 423 is formed of a plate-like light transmitting member body 423a and a columnar extended portion 423b extending downward from the lower surface of light transmitting member body 423a. Light transmitting member 423 is preferably made of glass having a high moisture resistance and a sufficient hydrolytic resistance. It is further preferable to reduce a content of potassium or sodium, which may cause a problem in semiconductor chip 431, in light transmitting member 423. In this example, quartz glass is used as light transmitting member 423 satisfying the above conditions.

A lower end portion of extended portion 423b of light transmitting member 423 extends through substrate 411, and a lower end surface of extended portion 423b is externally exposed. Solder bumps 453 are formed on the lower surface of light transmitting body 423a of light transmitting member 423 for connection to electrode 412 formed on the surface of substrate 411. Light transmitting member 423 may be used as a base member, and an interconnection may be arranged on the surface of light transmitting member 423. This interconnection can be connected to electrode 412 via solder bump 453.

Semiconductor chip 431 is arranged above light transmitting member 423 with a space 461 therebetween. Semiconductor chip 431 is provided at its lower surface with the electrode, which is connected to electrode 424 of base member 421 via solder bump 432, and thereby is electrically and mechanically connected to base member 421. If semiconductor chip 431 is a camera-compatible chip for a cellular phone, light transmitting member 423 can lead external light to semiconductor chip 431, and thus semiconductor chip 431 can receive the external light.

According to the above structure of the semiconductor device of this embodiment, semiconductor chip 431 may be the camera-compatible chip, which is required to receive the external light. In this case, the above structure is preferable because it can supply the external light to semiconductor chip 431. Light transmitting member 423 is provided at its surface with the interconnections and electrodes, and thereby can be used as an insulated circuit board for providing wiring or interconnections of semiconductor chip 431.

(Fifth Embodiment)

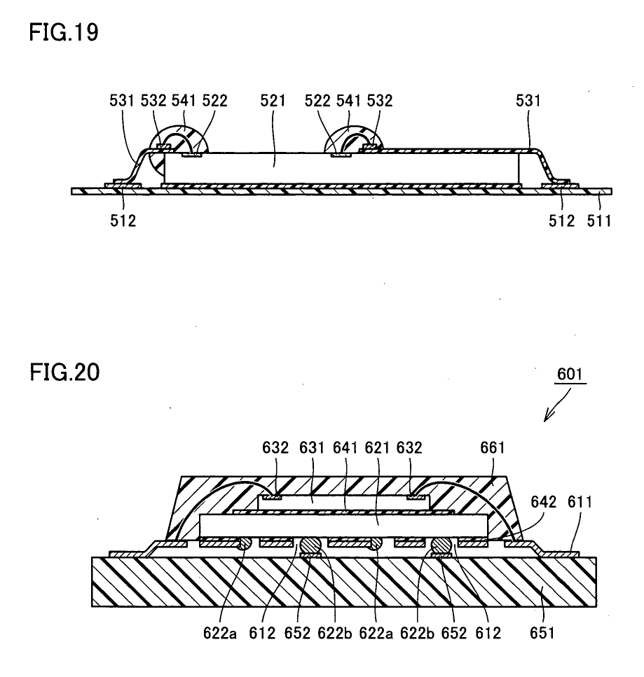

A semiconductor device of a fifth embodiment according to a fifth invention will now be described with reference to FIGS. 18 and 19.

A semiconductor device 501 of this embodiment includes a circuit board 511, a semiconductor chip 521 arranged on circuit board 511, and flexible substrates 531 each having a first end coupled to circuit board 511 and a second end coupled to semiconductor chip 521. Bumps 522 formed on semiconductor chip 521 are electrically connected to terminals 532 formed on flexible substrate 531, respectively.

Circuit board 511 includes a base member formed of epoxy resin, electrodes 512 formed on the surface of the base member, and interconnections (not shown). Each electrode on circuit board 511 is connected to an end of the interconnection of belt-like flexible substrate 531 by soldering. Flexible substrate 531 is formed of a base member such as polyimide film and interconnections, which are made of copper foil and are laid over the base member.

Flexible substrate 531 is provided at the other end with terminals 532 connected to interconnections. Terminals 532 are connected to pads 522 arranged on the upper surface of semiconductor chip 521 by wire bonding. Instead of the wire bonding, another connection structure may be used for electric connection of terminal 532.

The interconnection formed on flexible substrate 531 is thicker than a thin metal line used in the wire bonding or the like. In this embodiment, flexible substrate 531 is connected to the surface of semiconductor chip 521, and terminals 532 of flexible substrate 531 are located near pads 522 of semiconductor chip 521. Thereby, terminals 532 are located near pads 522 so that the length of the thin metal line, which is used in the wire bonding, can be minimized. This can provide a structure compatible with fast signals using high-frequency currents.

Pads 522 of semiconductor chip 521 may be arranged on an outer peripheral portion of the main surface of semiconductor chip 521, in which case flexible substrate 531 is connected to the outer periphery of semiconductor chip 521, and flexible substrate 531 and pads 522 are connected by wire bonding.

As shown in FIG. 19, pad 522 of semiconductor chip 521 may be arranged in a central portion of the main surface of semiconductor chip 521, in which case flexible substrate 531 is extended to the central portion of semiconductor chip 521, and is connected to pad 522 in the central position by wire bonding. Thereby, even in the structure having pad 522 arranged in the central portion of semiconductor chip 521, the length of the thin metal line can be minimized, and the structure can be compatible with high-frequency signals.

A sealing member 541 may be arranged to cover only a portion near the wire bonding portion. Since sealing member 541 arranged only in the portion near the wire bonding portion covers the thin metal wires in the wire bonding portion, which are less resistant to an external force, it can protect the thin metal wires. Since sealing member 541 is not provided for flexible substrates 531, which have a certain resistance to the external force, it is possible to minimize an amount of sealing member, and thus to reduce a weight of the semiconductor device.

(Sixth Embodiment)

A semiconductor device and a method of manufacturing the semiconductor device of a sixth embodiment according to a sixth invention will now be described with reference to FIGS. 20 to 22.

A semiconductor device 601 of this embodiment includes a lead frame 611, a first semiconductor chip 621 having a first main surface opposed to a main surface of lead frame 611 and fixed thereto, and a second semiconductor chip 631 fixed onto a second main surface of first semiconductor chip 621. Lead frame 611 has openings 612 in positions, which correspond to at least one of electrodes 622 formed on the first main surface of first semiconductor chip 621.

As shown in FIG. 20, semiconductor device 601 of this embodiment includes first and second semiconductor chips 621 and 631 stacked together in a vertical direction. First and second semiconductor chips 621 and 631 are fixed together by a diebond material 641.

Each of semiconductor chips 621 and 631 contains a semiconductor element, and has a function surface defined by an external surface not opposed to the function surface of the other semiconductor chip. Thus, first semiconductor chip 621 has the function surface opposed to lead frame 611. Second semiconductor chip 631 has the function surface defined by an upper surface in FIG. 20. Each of first and second semiconductor chips 621 and 631 is provided at the function surface with electrodes. First and second semiconductor chips 621 and 631 are sealingly covered with a sealing member 661.

In second semiconductor chip 631, electrodes 632 are connected to lead frame 611 by wire bonding.

First semiconductor chip 621 is provided at its function surface, i.e., the lower surface in FIG. 20 with the plurality of electrodes 622. Electrodes 622 are formed of solder bumps. Among electrodes 622, electrodes 622a and 622b extend through openings 612 in lead frame 611. Electrodes 622a and 622b are connected to electrodes 652 of a substrate 651. Other electrodes 622a and 622c are connected to lead frame 611.

Lead frame 611 is provided at its outer periphery with a plurality of tie-bars 613. Each tie-bar 613 has a plated portion 613a at its tip end. Plated portion 613a is connected to electrode 632 of second semiconductor chip 631 by wire bonding.

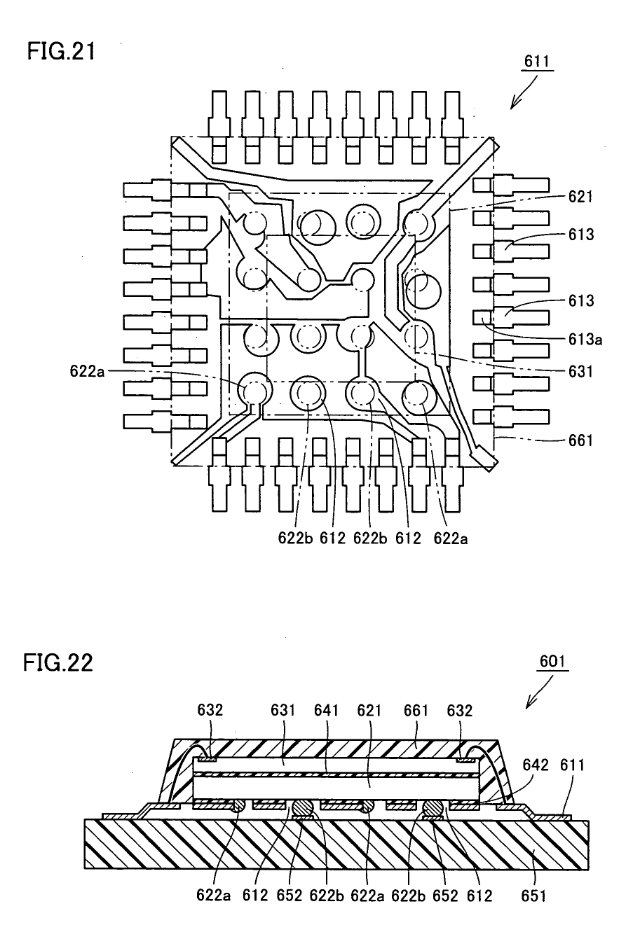

Lead frame 611 has an interconnection pattern shown in FIG. 21 so that it can provide wiring between first and second semiconductor chips 621 and 631. Electrode 622b of first semiconductor chip 621 is connected to lead frame 611. Another electrode 622a extends through opening 612 in lead frame 611. Thus, electrode 622a is externally exposed without contact with lead frame 611.

Since this embodiment has the structure described above, the plurality of electrodes 622 formed on the lower surface of the lower semiconductor chip, i.e., first semiconductor chip 621 can be selectively connected to an external portion or lead frame 611. For external connection of electrode 622b, opening 612 is formed in lead frame 611, and electrode 622b is externally exposed without contact with lead frame 611. For connecting electrode 622a to lead frame 611, lead frame 611 is configured to have an interconnection pattern partially overlapping with target electrode 622a.

In a modification shown in FIG. 22, first and second semiconductor chips 621 and 631 have the same planar form. The semiconductor device of this modification can be manufactured in the following method.

First, processing is performed to prepare first semiconductor chip 621, which has the main surface provided with electrodes 622, and second semiconductor chip 631, which has the main surface provided with electrodes 632. Then, first and second semiconductor chips 621 and 631 are stacked to locate electrodes 622 and 632 on outer sides, respectively, and are adhered together by a diebond material 641. Thus adhesion provides a both-side semiconductor chip structure, of which opposite main surfaces provide the function surfaces, respectively. Then, the both-side semiconductor chip assembly thus integrated is fixed onto lead frame 611 by diebond material 641.

This manufacturing method facilitates the manufacturing, as compared with a manner, in which first semiconductor chip 621 is adhered to lead frame 611, and then thin second semiconductor chip 631 is fixed to first semiconductor chip 621. If first and second semiconductor chips 621 and 631 are to be successively layered, first and second thin semiconductor chips 621 and 631 must be individually handled, which requires complicated operations.

In contrast to the above, the manufacturing method of this embodiment fixes first and second semiconductor chips 621 and 631 together in advance, and then fixes them to lead frame 611. Therefore, the operation of individually handling semiconductor chips 621 and 631 can be performed in a situation allowing easy adhering operation. This improves the manufacturing efficiency.

In a manufacturing method of a semiconductor device according to a modification of this embodiment, first and second semiconductor chips 621 and 631 have the same planar form. This facilities positioning, e.g., in an operation of adhering them together, and thus further improves the manufacturing efficiency.

Although the present invention has been described and illustrated in detail, it is clearly understood that the same is by way of illustration and example only and is not to be taken by way of limitation, the spirit and scope of the present invention being limited only by the terms of the appended claims.

1. A semiconductor device comprising:
a circuit board having first and second main surfaces, and provided at said fist main surface with an electrode;
a semiconductor chip connected to said second main surface of said circuit board;
a sealing member sealingly covering said circuit board and said semiconductor chip while exposing said first main surface of said circuit board; and
a coupling portion allowing coupling to a neighboring semiconductor device.

2. The semiconductor device according to claim 1, wherein
said semiconductor device has a substantially rectangular outer form.

3. The semiconductor device according to claim 1, wherein
said coupling portion can couple the neighboring semiconductor devices in either the state of directing said first main surfaces in the same direction, or the state of directing said first main surfaces in the opposite directions, respectively.

4. The semiconductor device according to claim 1, wherein
said coupling portion can couple the neighboring semiconductor devices each having the main surface inclined with respect to the main surface of the other.

5. The semiconductor device according to claim 1, wherein
said coupling portion can couple the neighboring semiconductor devices while providing a stepped portion between the main surfaces.

6. The semiconductor device according to claim 1, further comprising:
a connecting portion for electric connection to a neighboring semiconductor device.

7. The semiconductor device according to claim 6, wherein
said connecting portion includes a flexible substrate electrically connected to a neighboring semiconductor device.

8. A semiconductor module, wherein
a plurality of semiconductor devices according to claim 1 are coupled together, and electronic parts are connected to said first main surface via said electrodes.

9. A method of manufacturing a semiconductor module comprising the steps of:
arranging a plurality of semiconductor devices each including a circuit board having first and second main surfaces, a semiconductor chip connected to said first main surface of said circuit board and a sealing member sealingly covering said circuit board and said semiconductor chip while exposing said second main surface of said circuit board on an adhesive surface of an adhesive tape in an expanded state; and
shrinking said adhesive tape to couple said plurality of semiconductor devices together by bringing said plurality of semiconductor devices into intimate contact with each other.

10. A semiconductor device comprising:
a plurality of semiconductor chips coupled together via a stress absorbing layer, wherein
one or some of said plurality of semiconductor chip(s) have main surface(s) inclined with respect to the main surface(s) of the other semiconductor chip(s).

11. A semiconductor device comprising:
a substrate;
a base member having a first main surface opposed to said substrate and fixed onto said substrate; and
a semiconductor chip fixed to a second main surface of said base member, wherein
said base member is provided at a portion not overlapping with said semiconductor chip with an electrically conductive member extending from said first main surface of said base member to the second main surface,
a side of said electrically conductive member near said first main surface is connected to an electrode arranged on said substrate, and
a side of said electrically conductive member near said second main surface is electrically connected directly or via an interconnection to an electrode of said semiconductor chip.

12. A semiconductor device comprising:
a base member; and
a semiconductor chip fixed to a first main surface of said base member, wherein
said base member is formed of a base member body, and a light transmitting member extending through said base member body, and
a sealing member sealingly covers said semiconductor chip and said base member while externally exposing at least a portion of said light transmitting member, and said light transmitting member leads external light to said semiconductor chip.

13. A semiconductor device comprising:
a circuit board;
a semiconductor chip arranged on said circuit board; and
a flexible substrate having a first end coupled to said circuit board and a second end coupled to said semiconductor chip, wherein
a pad formed on said semiconductor chip is electrically connected to a terminal formed on said flexible substrate.

14. A semiconductor device comprising:
a lead frame;
a first semiconductor chip fixed to a main surface of said lead frame, and having a first main surface opposed to the main surface of said lead frame; and
a second semiconductor chip fixed to a second main surface of said first semiconductor chip, wherein
said lead frame has an opening in a position corresponding to at least one of electrodes formed on the first main surface of said first semiconductor chip.
